(19) United States
(12) Patent Application Publication
(10) Pub. No.: US 2013/0263911 A1
(43) Pub. Date: Oct. 10, 2013

(54) INTEGRATED HYBRID GENERATOR

(71) Applicant: Thomas Patrick Bryson, Brantford (CA)

(72) Inventor: Thomas Patrick Bryson, Brantford (CA)

(21) Appl. No.: 13/990,136

(22) PCT Filed: Nov. 28, 2011
(86) PCT No.: PCT/CA11/01280

§ 371 Date: Jun. 25, 2013

Related U.S. Application Data
(60) Provisional application No. 61/417,591, filed on Nov. 29, 2010.

(51) Int. Cl. H01L 31/042; F03D 3/04

(52) U.S. Cl. CPC H01L 31/0422; F03D 3/0445
USPC 136/244; 415/224

(57) ABSTRACT

Disclosed is a device for harvesting energy from an air current, the device comprising: a) one or more wind turbines, each wind turbine comprising a vane assembly rotatably mounted on a shaft, the vane assembly comprising a plurality of vanes; and b) an aerodynamic deflector mounted FIG. 1A over the one or more turbines, the deflector comprising an opening associated with each wind turbine; wherein the deflector shields the vane assembly from upwind drag, and the opening channels the air current onto a portion of the vane assembly. The deflector can further comprise a plurality of photovoltaic solar cells for harvesting solar energy. Similarly, each of the plurality of vanes can comprise one or more photovoltaic solar cells for harvesting solar energy. The device can be mounted on a mobile body or stationary body. The vane assembly can be mounted on a horizontal shaft or vertical shaft.

### TECHNICAL FIELD

The present disclosure relates to the field of renewable energy. In particular, the present disclosure relates to the harvesting of wind energy, and optionally, solar energy.

### BACKGROUND

Wind has been harvested as a way of converting kinetic energy into a useable output of work for millennia, most commonly in sailing ships and windmills. In modern times, the focus on wind and wind-power has become synonymous with the green energy movement as a way of generating renewable eco-friendly electricity.

Similarly, devices have been created as energy converters which transform solar energy into electricity by way of photovoltaic technology, commonly referred to as “solar panels”.

There have also been attempts to combine the capture of wind and solar energies into one device.

US Patent Application No. 20100181958A1 (Caudill) discloses an environmental power generation device that includes a base, a turbine mounting structure carried by the base and a wind turbine carried by the turbine mounting structure. The environmental power generation device also includes a power generator in communication with the wind turbine. The power generator includes a rotor in communication with the wind turbine and a stator in rotational communication with the rotor. The environmental power generation device also includes a solar cell mounting structure connected to the base, and a solar cell connected to the solar cell mounting structure and positioned to overlie the wind turbine. In addition, the environmental power generation device also includes a cover to be connected to the base and positioned to overlie the turbine mounting structure and the mounting track.

U.S. Pat. No. 4,553,037 (Veazy) discloses a solar breeze power package having sail and windmast options useful both on land and sea and especially useful in a saucer ship type design. The Vertical Axis Wind Turbine (VAWT) of the several Darrieus designs in conjunction with roll-up or permanently mounted solar cells combine in a hybrid or are used separately to provide power to a battery bank or other storage device.

US Patent Application No. 20100183443 A1 (Thorne et al.) discloses a system for collecting wind and solar energy including a tower, a wind turbine, and a solar energy collector. The solar energy collector has a vertically oriented frame attached to the wind turbine. The solar energy collector is rotatably coupled to the bottom end of the tower to enable the vertically oriented frame and the wind turbine to rotate together about the tower axis. The vertically oriented frame has one or more photovoltaic panels for collecting solar energy. The solar energy collector can act as a wind foil to rotate the attached wind turbine in the direction of the wind. Alternatively, a motor can rotate the solar energy collector and wind turbine.

WO 2011/134054 (Bryson) discloses a hybrid wind-solar energy device comprising: a) a wind-capture assembly comprising: i) one or more wind sails evenly distributed circumferentially around a central axis thereof; and ii) a solar-energy capture means on an outer of the wind-capture assembly; and c) a turbine assembly comprising an anchoring based, an electrical generator, and an output shaft; the wind-capture assembly rotatably mounted on the output shaft and coupled thereto; the hybrid wind-solar energy device configured to convert energy harnessed by the wind-capture assembly to electrical energy, wherein interaction of the one or more wind sails with wind induces rotation of the wind-capture assembly and turbine assembly round the central axis; and the outer surface of the wind capture assembly is directly exposed to sunlight throughout daylight hours.

Conventional wind-capture technology suffers from inefficiency due to drag of wind turbine vanes that rotate into wind (called “upwind drag”). That is, rotation of the turbine occurs when an incoming wind current pushes vane surfaces down wind (i.e. in the direction of the wind current). However, as the turbine rotates, vanes also rotate into the wind (i.e. “upwind”), thereby causing drag. The “windward ratio”, is a measure of the drag, based on the power generated by rotation in the downwind direction, minus the effect of friction and drag on the other half of the unit that is moving into the upwind direction.

### SUMMARY

Disclosed herein is an integrated hybrid generator that provides an integrated solution for the generation of alternative energy, local or onboard use of the energy, and storage and/or delivery of renewable energy.

According to one aspect, there is provided a device for harvesting energy from an air current, the device comprising: a) one or more wind turbines, each wind turbine comprising a vane assembly rotatably mounted on a shaft, the vane assembly comprising a plurality of vanes; and b) an aerodynamic deflector mounted over the one or more turbines, the deflector comprising an opening associated with each wind turbine; wherein the deflector shields the vane assembly from upwind drag, and the opening channels the air current onto a portion of the vane assembly.

The deflector can further comprise a plurality of photovoltaic solar cells for harvesting solar energy. Similarly, each of the plurality of vanes can comprise one or more photovoltaic solar cells for harvesting solar energy. The device can be mounted on a mobile body or stationary body. The vane assembly can be mounted on a horizontal shaft or vertical shaft. When a horizontal shaft is used, the vanes can be curvilinear, and the wind turbine can be a dual turbine, single rotor generator.

When the device is mounted on a stationary body, the air current is primarily natural wind, the deflector can be rotatably mounted on one wind turbine, and the deflector further comprises a deflector vane.

The energy harvested from the device can be stored in one or more energy storage devices. Examples of such storage devices include a lead acid battery or a lithium ion ferrite battery.

In another aspect, there is provided a device for harvesting energy from an air current, the device comprising: a) one or more wind turbines, each wind turbine comprising a vane assembly rotatably mounted on a horizontal shaft, the vane assembly comprising a plurality of curvilinear vanes; and b) an aerodynamic deflector mounted over the one or more turbines, the deflector comprising an opening associated with each wind turbine; wherein the device is placed on a mobile body; the deflector shields the vane assembly from upwind drag, and the opening channels the air current onto a portion of the vane assembly.

In yet another aspect, there is provided a device for harvesting energy from an air current, the device comprising: a) one or more wind turbines, each wind turbine comprising a vane assembly rotatably mounted on a vertical shaft, the vane assembly comprising a plurality of vanes; and b) an aerodynamic deflector mounted over the one or more turbines, the deflector comprising an opening associated with each wind turbine; wherein the device is placed on a mobile body; the deflector shields the vane assembly from upwind drag, and the opening channels the air current onto a portion of the vane assembly.

In yet a further aspect, there is provided a device for harvesting energy from an air current, the device comprising: a) one or more wind turbines, each wind turbine comprising a vane assembly rotatably mounted on a vertical shaft, the vane assembly comprising a plurality of vanes; and b) an aerodynamic deflector mounted over the one or more turbines, the deflector comprising an opening associated with each wind turbine, and a deflector vane; wherein the device is placed on a stationary body; the deflector shields the vane assembly from upwind drag, and the opening channels the air current onto a portion of the vane assembly.

The wind turbine harvests kinetic energy through transfer of wind energy acting upon its exposed vanes. This causes the vanes of the turbine to rotate. Such rotation of the vanes causes the centrally mounted output rotor shaft of the turbine/generator to turn inside the housing. The rotor shaft has a series of magnets radially affixed to it, and such rotation generates an electrical current output as the rotor magnets pass the stationary magnets and coils contained within the turbine housing.

When optional solar or photovoltaic cells are included in the integrated hybrid generator, energy is generated from the sun by photon bombardment. That is, specific light frequencies are captured and transformed into mili-amp outputs as they pass through each multi-layered photovoltaic cell. This output is then stored, or utilised as needed.

In addition, disclosed herein is a dual turbine, cylindrical generator that allows the use of two high output generators to be fitted to one rotor vane assembly in a low profile, highly efficient solution.

The integrated hybrid generator can be mounted onto a stationary or mobile body. Examples of a stationary body include (but are not limited to) the ground, on a building, atop a large advertising sign or highway notice board, a pole mount, etc.

Examples of a mobile body include (but are not limited to) a truck, a train, a bus, a car, a van, etc. Furthermore, where the device is mounted on to a mobile body, the height and tilt of the device are designed to allow the mobile body to comply with transportation regulations and clear tunnels, overpasses, bridges, and the like. In addition, the present device eliminates additional drag by fitting within the confines of the existing frontal area of the mobile body. The aerodynamic design of the device provides a smooth aero foil surface that further enhances the airflow over and around the moving vehicle.

Once the present device is affixed to a stationary or mobile host, electrical connections are made to transfer the output of the wind turbine assembly, via brushes, wires or such other method as practicable to send the generated current to an inverter, rectifier, control panel, battery bank or grid tied inverter. Similarly, when the present device includes an optional feature of solar capture, output of the solar photovoltaic panels is transferred by methods known in the art, to an inverter, rectifier, control panel, battery bank or grid tied inverter.

The present device generates an electrical current from wind turbine technology, and optionally, a plurality of solar photovoltaic cells. A control panel management system stores and transforms wind energy, and optionally solar energy, as an alternating current of any required voltage. For example, the current can be directed to storage batteries; or can feed directly into a grid or other electrical usage as may be required.

The integrated hybrid generator possesses numerous other benefits over conventional wind energy systems. Conventional wind turbines require considerable tower requirements to elevate the turbines to a workable height. This is often expensive, unsightly and difficult to service. The present device mounts directly onto a base and can be affixed at ground level, on a roof, on hi-way barriers, overhead signs, advertising placards, vehicle roofs, mobile applications or any location where portable power may be required.

Conventional wind turbines are exposed to the elements and require maintenance of broken blades, icing, furling, or corrosion of electrical components. The electrical parts of the present device are located inside the outer assembly of the wind turbines, while the vanes are never fully exposed to the elements. Furthermore, it is difficult and expensive to move or adjust a conventional wind turbine, whereas the present device is completely mobile and can be easily moved from location to location.

When solar technology is incorporated onto one or more of the vanes of the wind turbine, photovoltaic efficiency increases as the device surface is exposed to the sun's rays at all times without the use of mechanical or electrical actuation. Furthermore, there is a reduction of energy loss due to rain, ice and snow build-up on the photovoltaic cells (which are on the wind turbine vanes) by centrifugal shedding. Since the photovoltaic cells form part of the wind turbine, there is a dramatic reduction of wind damage on conventional PV panels by conversion of kinetic energy acting upon the panel into a rotary motion that generates additional electricity via internal turbine. Finally, cost is reduced since expensive fabricated mounting systems and automated sun seeker tracking systems are not required.

In addition, most solar energy systems include flat panels that rarely get exposed to direct sunlight on their entire surface. When photovoltaic cells are included, the present device is shaped to maximize exposure to direct sunlight.

There are further benefits when photovoltaic cells form part of the vanes of the wind turbine. For example, the spinning turbine exposes the entire photovoltaic surface to solar energy, eliminating the need for costly sun-tracking components. In addition, large, conventional solar panels are susceptible to wind damage, thereby requiring elaborate and substantial fabricated brackets. The present device, on the other hand, harvests wind power by allowing wind turbines to spin and generate power from the wind while exposing their entire outer surface to the sun. Furthermore, most conventional photovoltaic solar panels lose efficiency when covered with rain, snow or ice. The present device spins and uses centrifugal forces to shed vane surfaces of foreign objects.

The foregoing summarized the principal features of an integrated hybrid generator, and some of its optional aspects. The device may be further understood by the descriptions of the embodiments which follow. Whenever ranges of values are referenced within this specification, sub ranges therein are intended to be included within the scope of the device unless otherwise stated. Where characteristics are attributed to one or another variant of the device, unless otherwise indicated, such characteristics are intended to apply to all other variants of the device where such characteristics are appropriate or compatible with such other variants.

### BRIEF DESCRIPTION OF THE DRAWINGS

FIGS. 1A and 1B illustrate an exploded view and assembled view, respectively, of a first embodiment of an integrated hybrid generator.

FIGS. 2A and 2B illustrate an exploded view and assembled view, respectively, of a second embodiment of an integrated hybrid generator.

FIGS. 3A and 3B illustrate different tilt angles of the deflector shown in FIG. 2B.

FIGS. 4A and 4B illustrate the embodiments shown in FIGS. 3A and 3B, on the top surface of a cab.

FIGS. 5A and 5B illustrate an exploded view and assembled view, respectively, of a third embodiment of an integrated hybrid device.

FIG. 6 illustrates a perspective view of the dual turbine, single rotor, rooftop generator and mounting frame shown in FIG. 5A

FIGS. 7A and 7B illustrate respectively, a side sectional view of a deflector, and assembled integrated hybrid generator of FIG. 5B.

FIGS. 8A-8C illustrate the embodiment of FIG. 5B affixed to different varieties of a mobile body.

FIG. 9 illustrates an exploded view of a fourth embodiment of an integrated hybrid generator.

FIGS. 10A and 10B illustrate the embodiment shown in FIG. 9.

FIGS. 11A-11C illustrate, respectively, a top view, front view and side view of a fifth embodiment of an integrated hybrid generator.

FIGS. 12A and 12B each illustrate an example of a vane assembly for use in an integrated hybrid generator.

### DETAILED DESCRIPTION OF PREFERRED EMBODIMENTS

This detailed description is not intended to represent the only form in which the device may be assembled, operated, or utilized. This description serves only to illustrate the assembly and subsequent operation of the device. It should be noted however, that the assembly, operation, actuation and inter-relation of the various parts and subsequent processes may be achieved by different embodiments than that herein described, and although such departure may produce similar results, they are all intended to be encompassed within the scope of the device

### First Embodiment

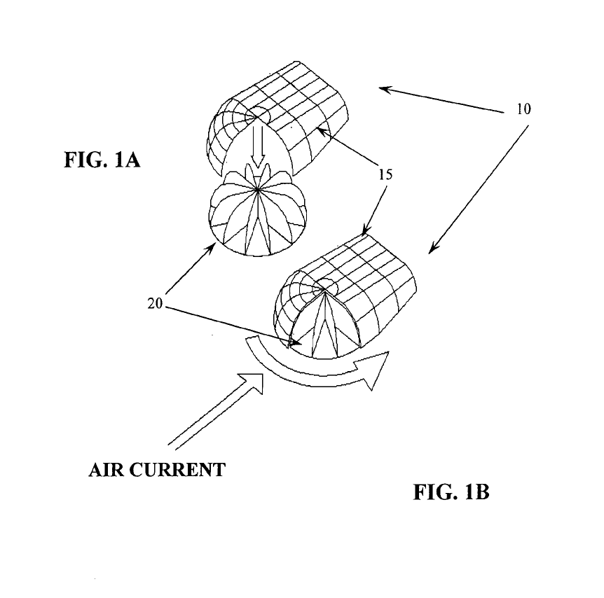

FIGS. 1A and 1B illustrate an exploded view and assembled view, respectively, of a first embodiment of an integrated hybrid generator (10).

In FIG. 1A, a deflector (15) and vane assembly (20) of a wind turbine are shown separately. The vane assembly (20) is rotatably mounted on a vertical shaft (not shown), which spins about a vertical axis. The deflector (15) can be aerodynamically streamlined, and has a cut-away portion to expose a plurality of vanes of the vane assembly (20).

In FIG. 1B, the deflector (15) is mounted on top of the vane assembly (20), such that only a portion of the vanes are exposed to the incoming air current, causing the vane assembly (20) to rotate about a vertical axis. It should be noted that the structure of the deflector (15) shields the vanes that are rotating upwind (i.e. into the air current). That is, the deflector shields the air current from the vanes that are moving in the upwind direction completely, while exposing only those vanes that are moving in the downwind direction (i.e. with the incoming air current).

The portion of the exposed vane assembly is not constrained, but can vary so that a peak efficiency of rotation is obtained. In the embodiment shown in FIGS. 1A and 1B, about 25% of the vane assembly is exposed to the incoming vane current.

Furthermore, the surface of the vane assembly (20) can be optionally covered partially, or completely, with a plurality of photovoltaic solar cells, thereby generating and storing energy from the sun.

In addition, the outer surface of the deflector can be optionally covered partially, or completely, with a plurality of photovoltaic solar cells, thereby generating and storing energy from the sun. In addition, the deflector can be contoured to fit the contour of the vane assembly.

The embodiment shown in FIG. 1B can be mounted onto a roof of a vehicle. In addition, one or more of the roof-mounted generator, can be used as space allows. The air current that acts upon the device is in a direction opposite to that of the moving vehicle.

### Second Embodiment

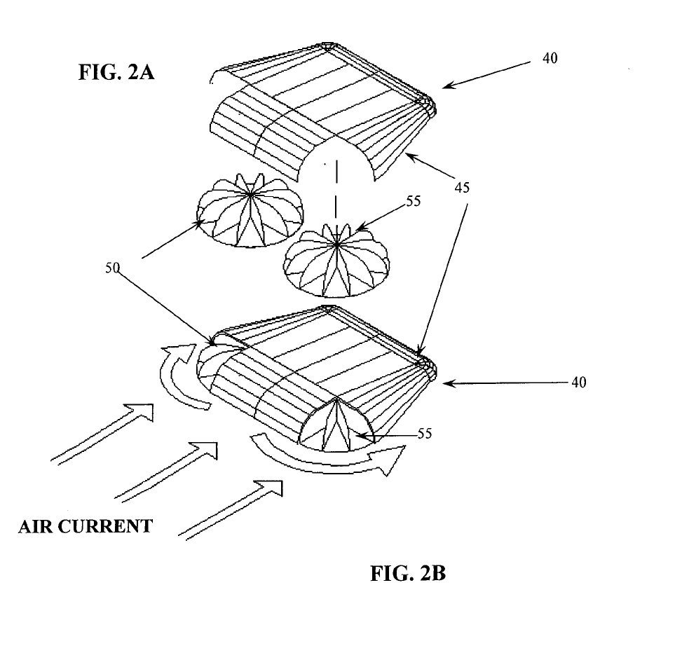

FIGS. 2A and 2B illustrate an exploded view and assembled view, respectively, of a second embodiment of an integrated hybrid generator (40). Here, the deflector (45) is mounted onto two vane assemblies (50, 55). As in the previous embodiment the deflector (45) is cut away to expose a portion of each of the vane assemblies (50, 55) to the air current. Each vane assembly (50, 55) forms part of its respective turbine—each vane assembly is rotatably mounted onto a vertical turbine shaft (not shown).

As in the previous embodiment, one, or both vane assemblies (50, 55) can be optionally covered partially, or completely, with a plurality of photovoltaic solar cells. Similarly, the outer surface of the deflector (45) can be optionally covered partially, or completely, with a plurality of photovoltaic solar cells. In addition, the deflector (45) can be contoured to fit the contour of each vane assembly (50, 55).

In FIG. 2B, the vane assemblies (50, 55) are shown in a counter rotating configuration for balance. However, other configurations are possible. In addition, more than one such “twin turbine” generator can be mounted onto the roof of a vehicle, as space permits.

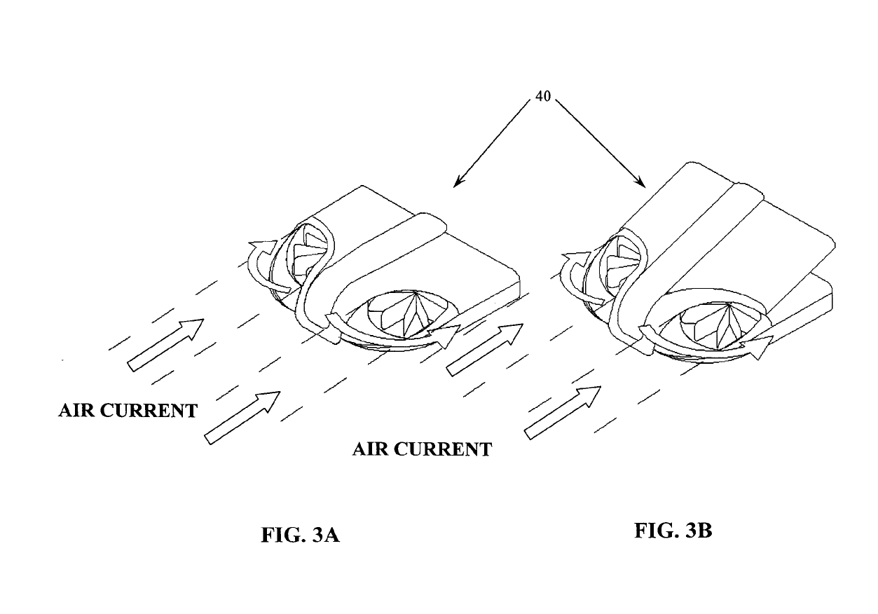

In order to minimize wind resistance on higher trailers, the device (40) can have a deflector that tilts; FIGS. 3A and 3B illustrate different tilt angles of the deflector (45) shown in FIG. 2B. FIG. 3A illustrates a low tilt angle, while FIG. 3B illustrates a higher tilt angle than that shown in FIG. 3A. This embodiment can be used for flatbeds, tankers, trains, electric vans or cars. In both FIGS. 3A and 3B, each set of dotted lines delineate a wind capture area for each respective turbine. The circular arrows indicate the direction of rotation of each turbine.

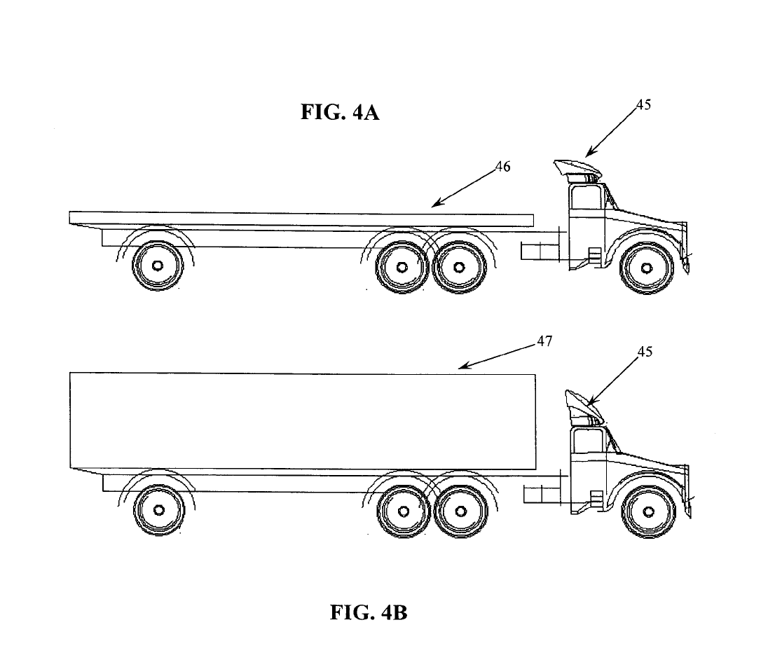

FIGS. 4A and 4B provide an illustration of the tilt mechanism being deployed, respectively, on a truck hauling a flatbed (46) (or tanker truck trailer), and a standard trailer (47). The turbines are still active in either orientation. However the drag is reduced by lowering the deflector (45) when there is a low profile trailer (46) or shorter payload.

### Third Embodiment

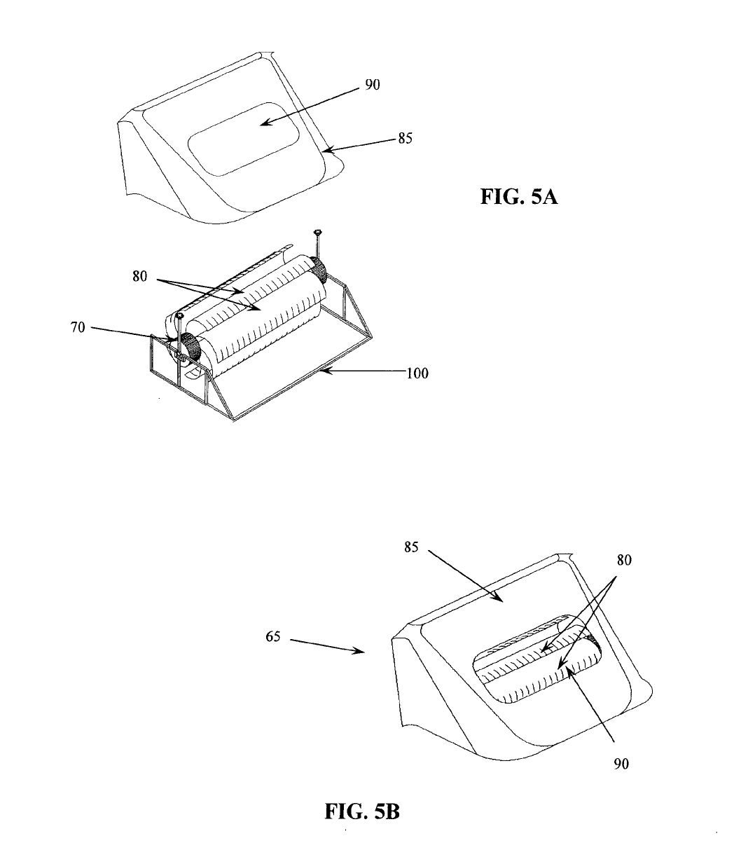

FIGS. 5A and 5B illustrate an exploded view and assembled view, respectively, of a third embodiment of an integrated hybrid generator (65).

Here, the turbine assembly (70) comprises a vane assembly which is rotatably mounted onto a horizontal shaft (not shown). The turbine assembly (70) is mounted onto a mounting frame (100), which in turn, affixes the device (65) onto a mobile body or stationary body. The vanes (80) of the vane assembly (75) can be curvilinear. The deflector (85) has a cut-away portion (90) that exposes only a portion of the vanes of the vane assembly (75) to an incoming air current.

In the assembled view of FIG. 5B, the opening (90) in the deflector (85) channels maximum airflow into the rotor vanes. Furthermore, the vanes that rotate into the wind are shielded by the deflector (85), to eliminate aerodynamic drag. The deflector (85) can be aerodynamic in design.

As in the previous embodiments, the individual vanes (80) of the vane assembly can be optionally covered partially, or completely, with a plurality of photovoltaic solar cells. Similarly, the outer surface of the deflector (85) can be optionally covered partially, or completely, with a plurality of photovoltaic solar cells.

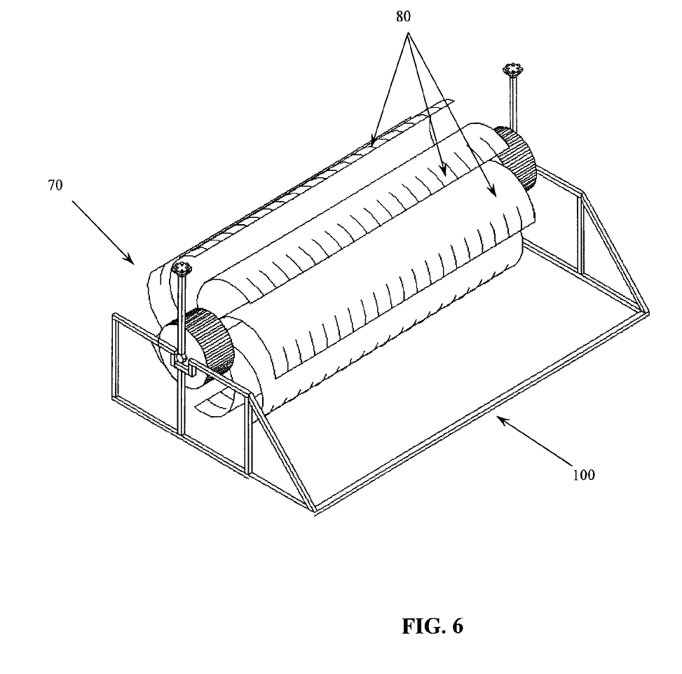

FIG. 6 illustrates a perspective view of the turbine assembly (70) and mounting frame (100) of the embodiment shown in FIG. 5A. The mounting frame affixes the turbine assembly (70) to the roof of a vehicle or building. It also allows for the deflector to be attached thereon. The rotating vanes are shown as (80).

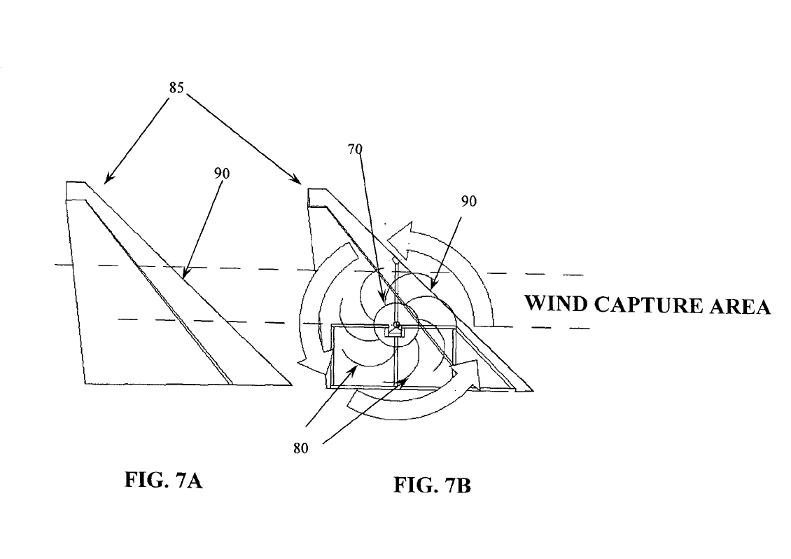

FIG. 7A and 7B illustrate respectively, a side sectional view of the deflector (85) and turbine assembly (70) of FIG. 5B, showing the configuration of the curvilinear vanes (80) in relation to the opening (90) within the deflector (85). The dotted lines represent the wind capture area, in which the air current is channeled through the deflector opening (90), onto vanes (80) which rotate in the downwind direction (indicated by the rotational arrows).

While the deflector (85) shown in this embodiment can be used for a truck, a low profile design can be made for trains and similar modes of transportation.

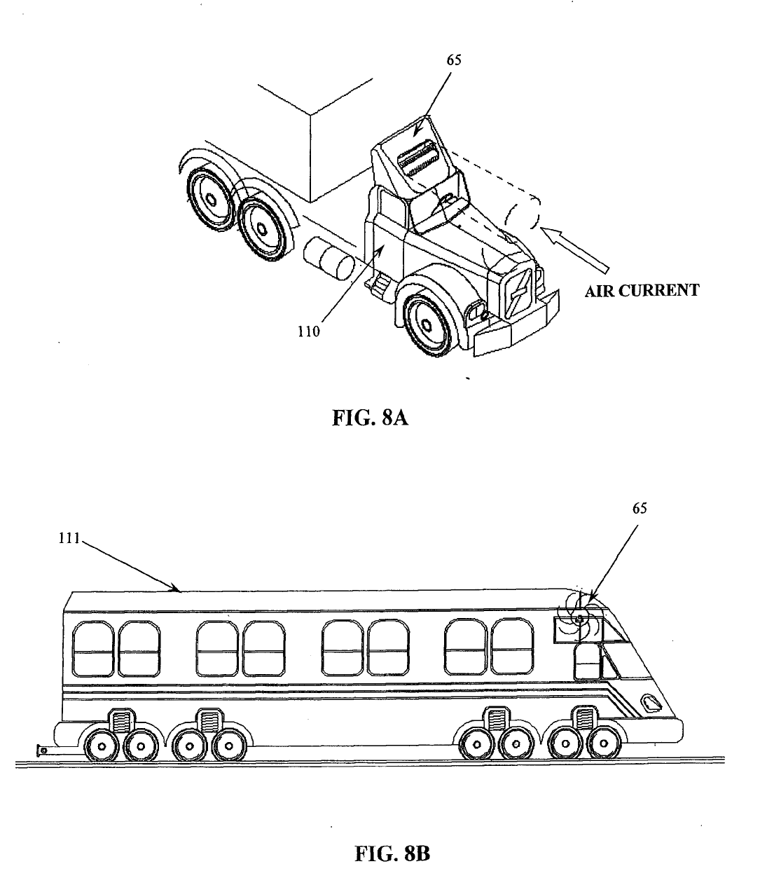

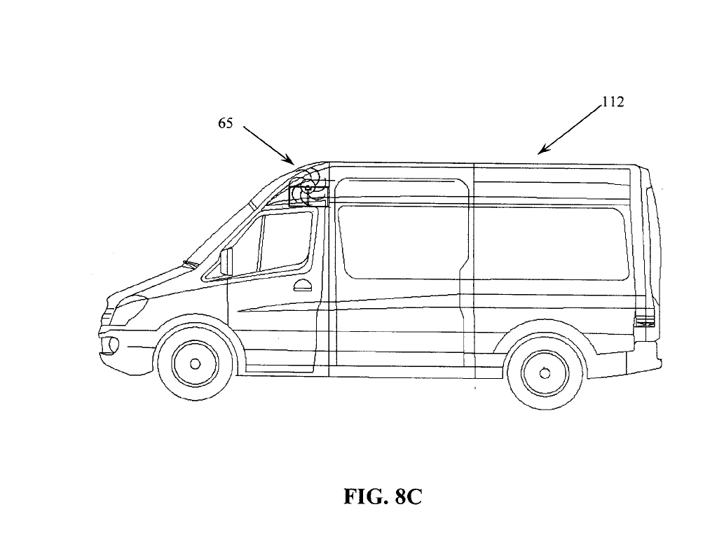

FIGS. 8A-8C illustrate use of the generator (65) on different types of mobile bodies.

FIG. 8A illustrates the integrated hybrid generator (65) of FIG. 5B on top of a cab (110) of a tractor trailer. The dotted lines delineate a boundary in which the incoming air current is channeled into the opening of the deflector. One or more of these generators (65) can be affixed, as space provides. Alternatively, the integrated hybrid generator (65) can be affixed within the mobile body, as shown in FIGS. 8B and 8C. This configuration can apply to a train (111) (as in FIG. 8B), or similar-shaped vehicles, such as (but not limited to) a “sprinter” type van (112) as in FIG. 8C.

While FIGS. 8B and 8C illustrate an integrated hybrid generator having a wind turbine with a horizontal axis of rotation, it is understood that one can also use a wind turbine with a vertical axis of rotation for a device that is affixed within a mobile body.

### Fourth Embodiment

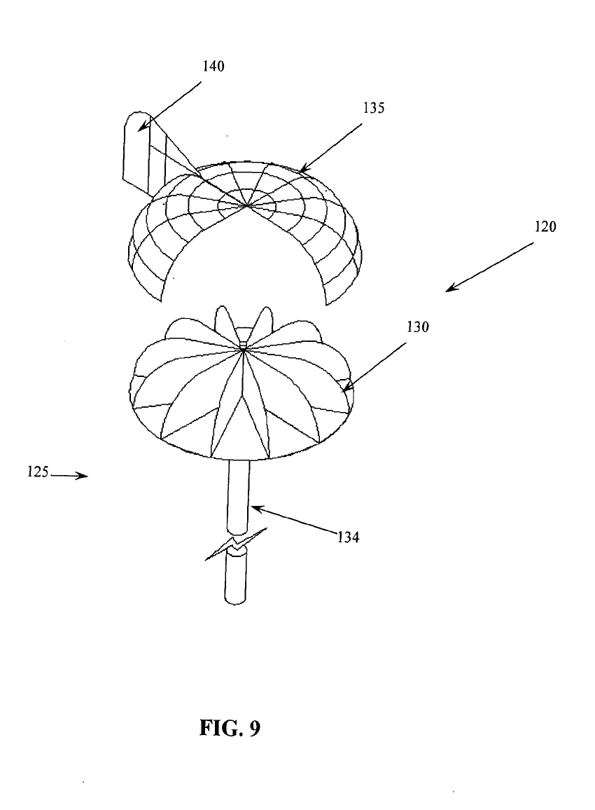

FIG. 9 illustrates an exploded view of a fourth embodiment of an integrated hybrid generator (120).

The turbine assembly (125) includes a vane assembly (130) rotatably mounted on a vertical shaft (134). The deflector (135) can be shaped to fit over the vane assembly (130), and can be aerodynamically designed. As in the previous embodiments, the deflector (135) has a cutaway portion to expose only that portion of the vanes that rotate in the downwind direction, while shielding those vanes that rotate in the upwind direction. However, the deflector (135) also includes a deflector vane (140), which enables the deflector (135) to rotate, so that the opening faces the incoming air current, and the deflector vane (140) is downwind.

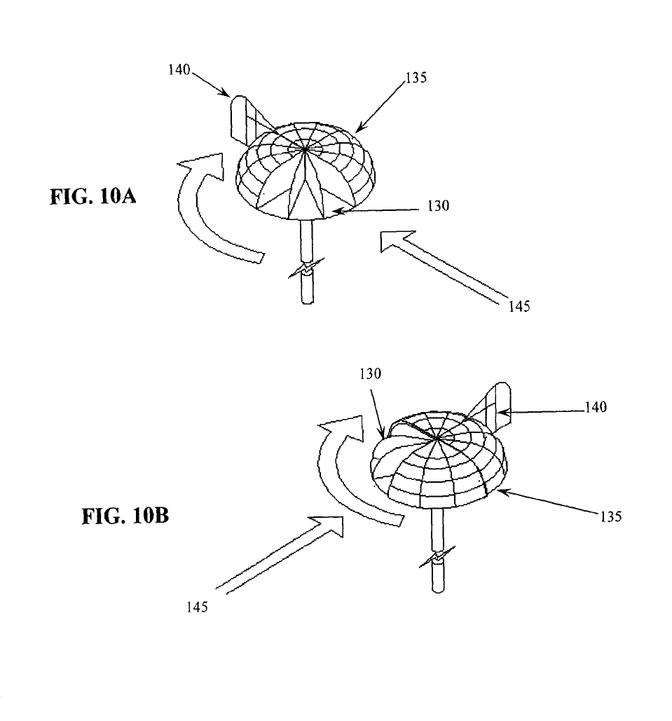

This is further illustrated in FIGS. 10A and 10B, in which the deflector (135) is rotatably mounted over the vane assembly (130). In FIG. 10A, the air current (145) is in the north-west direction, as is the deflector vane (140). In FIG. 10B, as the direction of the air current (145) shifts, it shifts the deflector vane (140), which in turn causes the deflector (135) to rotate, thereby exposing the downwind portion of the vanes to the incoming air current. That is, the deflector (135) rotates, so that the deflector opening is facing the incoming air current, and the deflector vane (140) is downwind. This adds to energy efficiency by shielding the upwind vanes from airflow drag.

As in the previous embodiments, the individual vanes of the vane assembly (130) can be optionally covered partially, or completely, with a plurality of photovoltaic solar cells. Similarly, the outer surface of the deflector (135) can be optionally covered partially, or completely, with a plurality of photovoltaic solar cells.

The integrated hybrid generator (120) can be used on any stationary body. Examples include, but are not limited to, the ground, a pole mount, a building rooftop, atop a large advertising sign or highway notice board, etc.). Here, the air current is primarily natural wind. One or more such generators (120) can be used, provided that space is available.

### Fifth Embodiment

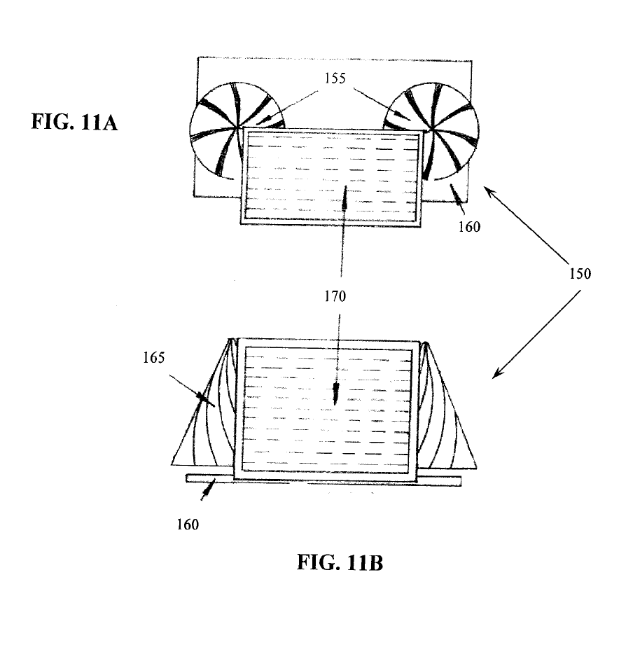

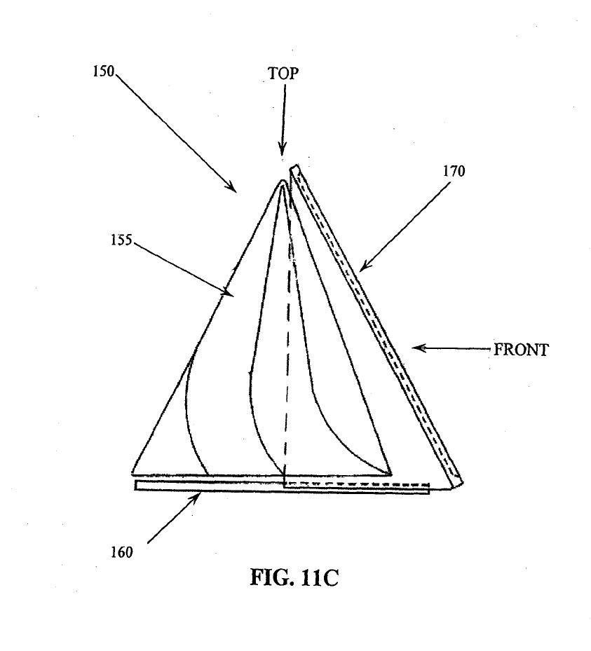

FIGS. 11A-11C illustrate, respectively, a top view, front view and side view of a fifth embodiment of an integrated hybrid generator (150).

Each turbine assembly (155) is mounted atop a base plate (160). The turbine assembly (155) can include a series of curvilinear vanes (165), rotatably mounted on a vertical shaft (not shown). The vane assembly shown in the embodiment of FIGS. 11A-11C has been previously disclosed in PCT publication WO 2011/134054. A deflector (170) is rigidly mounted on the base plate (160), such that a portion of the vanes of each turbine assembly (155) is exposed to an incoming air current, while a portion thereof is shielded by the deflector (170). While the embodiment shown in FIGS. 11A-C includes a deflector in the form of a solar panel, it is understood that the deflector (170) can be devoid of photovoltaic cells, thereby serving only to shield portions of the turbine assembly. When the deflector (170) includes photovoltaic cells, it is angled to optimize exposure of the cells to the sun.

As in the previous embodiments, the individual vanes (165) can be optionally covered partially, or completely, with a plurality of photovoltaic solar cells. In the embodiment shown in FIGS. 11A-C, the turbine assembly (155) is shaped to always collect direct sunlight; when it spins, the entire vane assembly surface is exposed to solar energy.

For example, the embodiment shown in FIGS. 11A-11C can be mounted onto either a mobile (e.g. truck, train, bus, car, van, etc.) or stationary body (e.g. the ground, on a building, atop a large advertising sign or highway notice board, etc.).

Examples of Vane Assemblies

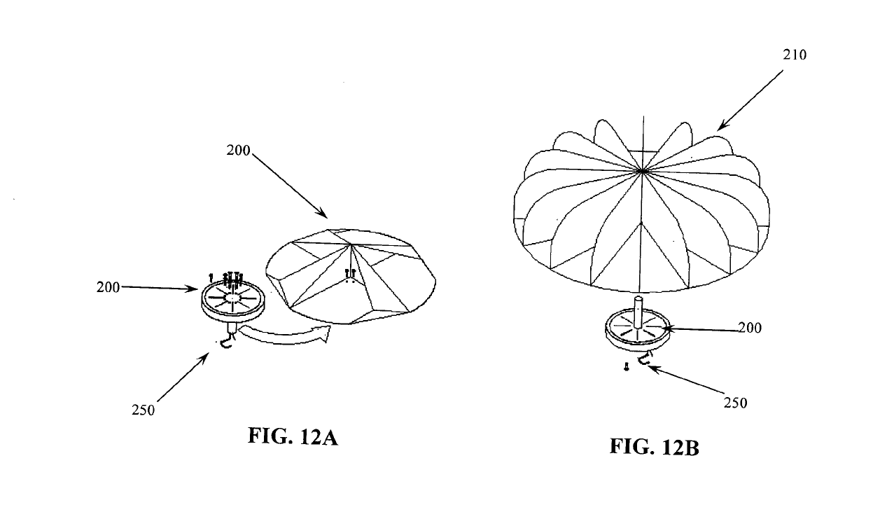

FIGS. 12A and 12B each illustrate an example of a vane assembly for use in an integrated hybrid generator. The vane assembly (200) shown in FIG. 12A is an example of the type disclosed in PCT publication WO 2011/134054, while the vane assembly (210) shown in FIG. 12B is an example of a standard vertical axis vane assembly. In both cases, the vane assembly (200 or 210) is bolted or fastened directly to the top of the turbine, while the electrical wires (250) exit through the output shaft into the mounting pole to keep connecting wires shielded from the elements.

Each figure illustrates a type of connection between the vane assembly and the output shaft. In FIG. 12A, the vane assembly (200) mounted with the output shaft (220) down. In FIG. 12B, the vane assembly (210) is mounted directly onto the output shaft (230).

Additional Features

It is understood that the number of wind turbines can vary from a minimum of one, to as many as needed for a given application. Furthermore, various forms of a vertical wind turbine can be used in the present device. As an example, the wind turbine shown in FIGS. 11A-C can be interchanged with the wind turbines shown in FIGS. 1-8 and 10, and vice versa.

The vanes can be made from any solid, rigid or semi-rigid material that is lightweight and strong. For example, this material can be aluminum, plastic, or composite material. The vanes can be manufactured by cutting, slitting, sawing, stamping, blanking, moulding, thermoforming, shearing or casting as is practicable for the material used to construct the vanes.

The vanes are affixed to a turbine or generator by fasteners known in the art. For example, this can include bolts, screws, rivets, swaging, or adhesives.

Where the integrated hybrid generator includes a solar energy capture feature, the vanes and/or the deflector includes a plurality of photovoltaic solar cells. As an example, the vanes can be constructed from photovoltaic solar cells or panels. Alternatively, the surface of each vane can be covered partially, or completely, with a plurality of photovoltaic solar cells, thereby generating and storing energy from the sun. The deflector can be constructed from photovoltaic solar cells or panels. Alternatively, the surface of the deflector can be covered partially, or completely, with a plurality of photovoltaic solar cells, thereby generating and storing energy from the sun.

The deflector can vary in design, depending on the application of the integrated hybrid generator. It can be made from any solid, rigid or semi-rigid material that is lightweight and strong. This can include, for example, aluminum, plastic, or composite material.

The deflector serves the additional purpose of channeling airflow directly into the downwind vanes of the various turbine designs for optimum output.

Tilting of any of the deflectors can be accomplished by electrical or mechanical actuation. This actuation can be a hydraulic or pneumatic cylinder attached at the base frame and to the moving portion of the deflector shield. A manual or electric screw actuation assembly can also cause the tilting to be effected. These are but a few examples of a tilting mechanism that is known by a worker skilled in the art.

Once the deflector and wind turbine assembly (or assemblies) are mounted and secured onto the base of a suitable host, connections for the transmission of current generated from the wind turbine(s), and optionally, solar panels, are connected to a control panel. Once an air current acts on the turbine, wind energy is harvested. In embodiments where the integrated hybrid generator includes photovoltaic cells, the harvesting of solar energy commences upon exposure of the generator to sunlight. In addition, there is additional solar energy efficiency when photovoltaic cells are affixed to the surface of the vanes. This is due the spinning of the turbine, which ensures that the entire surface area of the photovoltaic cells is in direct contact with the sun's rays.

Once assembled, the present device can be installed as a static, permanent fixture, or attached to a vehicle or other moving apparatus as a mobile fixture. The static or permanent version of the device generates electricity from the wind acting upon the vanes of the wind turbines, while the mobile version of the device generates electricity when the vehicle or other moving apparatus is in motion by inducing rotation of the vanes of the wind turbines. In each instance, this rotation initiates electrical generation through the wind turbines.

The integrated hybrid generator can be affixed outside a mobile body, or integrated within the mobile body. This applies whether the wind turbine has a vertical axis of rotation or a horizontal axis of rotation.

Furthermore, when the integrated hybrid generator is affixed onto a stationary body, the wind turbine can have a vertical axis of rotation, or a horizontal axis of rotation.

In summary, the present device provides a useable output of work, while producing minimal environmental impact. In addition, the device is scalable, and can be adjusted dimensionally to conform to specifications of size, space and function.

Applications

It is contemplated that this device can be used in a variety of potential applications due to the ability of the device to be scaled proportionately and easily relocated to areas where a portable supply of power is required. More specifically, the device provides an alternate energy hybrid device encompassing features of wind and solar generation technology, while offering significant advantages over existing wind or solar systems.

It is contemplated that the device in a small scale version of its current embodiment can be used in remote locations to deliver a continuous supply of electricity to a cellular repeater station or microwave tower.

The device can be used in a trailer-able form to provide emergency power in disaster zones, forward deployment military troop support, or as a portable power pack that can be towed to a remote location or rural abode void of a conventional power supply.

A mobile version of an integrated hybrid generator can be affixed to a vehicle such as a truck, trailer, train or bus, (as depicted in FIGS. 1-8 and 10). In a truck rooftop mounted application, the shape of the device acts as a wind deflector to divert air over and around the truck or trailer to provide increased fuel economy due to aerodynamic benefit.

A mobile version of an integrated hybrid generator allows for the onboard generation of electricity as the truck travels along the road via the wind turbines, and if also present, photovoltaic cells. This onboard electricity can be used for refrigeration units on the trailer to reduce the cost associated with transporting perishable goods, or stored in a battery bank that can be used to feed into the grid for credit, as part of a V2G Vehicle to Grid initiative.

In many developing regions of the world devoid of rudimentary electrical infrastructure from the grid or locally generated producers, the rooftop mobile version of the integrated hybrid generator could deliver fully charged “quick change” battery packs to these rural communities to comprise the basis of a small scale electrical utility. Every truck delivery to remote locations could include a supply of electricity by depositing a fully charged battery and picking up a depleted battery that will be recharged in a subsequent journey.

A major benefit of the mobile version of an integrated hybrid generator is to generate sufficient electrical energy during the day when the vehicle is in use, thereby allowing the trucker to shut off his diesel engine at night when the truck is parked in a truck stop. This single benefit can save up to 50% of the cost of diesel fuel, reduce wear and tear on the engine from idling 12-16 hours per day, and reduce green-house gas emissions.

The generation of onboard green renewable energy can permit truckers to benefit from Carbon Offsetting Credits (COC); can provide an additional revenue stream by selling the electricity back to the grid; or can power electric drive motors to reduce greenhouse gases from conventional internal combustion engines burning diesel or bio-fuels.

A mobile version of an integrated hybrid generator can also be used on sea containers mounted on ships to provide cooling for perishable cargo during a long sea voyage, or the electricity can be used for the ship's electrical requirements.

### CONCLUSION

The foregoing has constituted a description of specific embodiments showing how the device may be applied and put into use. These embodiments are only exemplary, and are not intended to limit or restrict the scope of the device. The invention in its broadest, and more specific aspects, is further described and defined in the claims which now follow.

These claims, and the language used therein, are to be understood in terms of the variants which have been described. They are not to be restricted to such variants, but are to be read as covering the full scope of the invention as is implicit within the disclosure that has been provided herein.

1. A device for harvesting energy from an air current, the device comprising:
a) one or more wind turbines, each wind turbine comprising a vane assembly rotatably mounted on a shaft, the vane assembly comprising a plurality of vanes; and
b) an aerodynamic deflector mounted over the one or more turbines, the deflector comprising: i) a cover portion associated with each wind turbine; and ii) an open portion associated with each wind turbine,
wherein the cover portion shields vanes in an upwind direction from the air current; and the open portion exposes at most one quadrant of the vane assembly in a downwind direction directly to the air current.

2. The device of claim 1, wherein:
i) the shaft is perpendicular to the air current, and lies in a plane that bisects the turbine into a first half and a second half, the plane parallel to the air current;
ii) the cover portion shields the first half of the turbine from the air current; and
iii) the open portion exposes the second half of the turbine to the air current.

3. The device of claim 1, wherein the deflector further comprises a plurality of photovoltaic solar cells for harvesting solar energy.

4. The device of claim 1, wherein each of the plurality of vanes comprises one or more photovoltaic solar cells for harvesting solar energy.

5. The device of claim 1, wherein the device is mounted on a mobile body.

6. The device of claim 1, wherein the vane assembly is rotatably mounted about a horizontal shaft.

7. The device of claim 6, wherein each of the plurality of vanes is curvilinear.

8. The device of claim 6, wherein the wind turbine is a dual turbine, single rotor generator.

9. The device of claim 5, wherein the vane assembly is rotatably mounted about a vertical shaft.

10. The device of claim 1, wherein:
a) the device is mounted on a stationary body and has one wind turbine;
b) the air current is primarily natural wind;
c) the deflector is rotatably mounted on the wind turbine,
d) the open portion defined in part by: a first edge of the cover portion and a second edge of the cover portion, a first vertical plane containing the first edge, the first vertical plane being at maximum ninety degrees from a second vertical plane containing the second edge; and
e) the deflector further comprises a deflector vane attached leeward to the cover portion such that a plane of the deflector vane is aligned with the first vertical plane;
such that the air current rotates the deflector relative to the wind turbine to a position where the cover portion shields vanes in an upwind direction from the air current; and the open portion exposes vanes in a downwind direction directly to the air current.

11. The device of claim 3 wherein energy harvested from wind or sun is stored in one or more energy storage devices.

12. The device of claim 11, wherein the energy storage device is a lead acid battery or a lithium ion ferrite battery.

13. A device for harvesting energy from an air current, the device comprising:
a) one or more wind turbines, each wind turbine comprising a vane assembly rotatably mounted on a horizontal shaft, the vane assembly comprising a plurality of curvilinear vanes; and
b) an aerodynamic deflector mounted over the one or more turbines, the deflector comprising: i) an open portion associated with each wind turbine; and ii) a cover portion associated with each wind turbine,
wherein the device is placed on a mobile body; each open portion exposes at most one quadrant of the vane assembly in a downwind direction to the air current; and the covering portion shields the remaining half of the wind turbine from the air current, thereby shielding vanes in an upwind direction from the air current.

14. The device of claim 13, wherein the device is placed on an outer surface of the mobile body.

15. The device of claim 14, wherein the mobile body is a truck or tractor.

16. The device of claim 13, wherein the device is placed within the mobile body.

17. The device of claim 16, wherein the mobile body is a train or sprinter van.

18. The device of claim 13, wherein the deflector further comprises a plurality of photovoltaic solar cells for harvesting solar energy.

19. The device of claim 13, wherein each of the plurality of vanes comprises one or more photovoltaic solar cells for harvesting solar energy.

20. A device for harvesting energy from an air current, the device comprising:
a) one or more wind turbines, each wind turbine comprising a vane assembly rotatably mounted on a vertical shaft, the vane assembly comprising a plurality of vanes; and
b) an aerodynamic deflector mounted over the one or more turbines, the deflector having: i) a cover portion associated with each wind turbine;
and ii) an open portion associated with each wind turbine,
wherein the device is placed on a mobile body; the cover portion shields vanes in an upwind direction from the air current; and each open portion exposes at most one quadrant of the vane assembly in a downwind direction directly to the air current.

21. The device of claim 20, wherein the deflector further comprises a plurality of photovoltaic solar cells for harvesting solar energy.

22. The device of claim 20, wherein each of the plurality of vanes comprises one or more photovoltaic solar cells for harvesting solar energy.

23. The device of claim 20, wherein the device is placed on an outer surface of the mobile body.

24. The device of claim 20, wherein the device is placed within the mobile body.

25. The device of claim 20, comprising two wind turbines.

26. The device of claim 20 wherein the deflector is tilted upward relative to a horizontal plane.

27. A device for harvesting energy from an air current, the device comprising:
a) a wind turbine comprising a vane assembly rotatably mounted on a vertical shaft, the vane assembly comprising a plurality of vanes; and
b) an aerodynamic deflector rotatably mounted over the wind turbine, the deflector comprising i) a cover portion with an opening that exposes at most a quadrant of the vane assembly, the opening defined in part by: a first edge of the cover portion and a second edge of the cover portion, a first vertical plane containing the first edge, the first vertical plane being at maximum ninety degrees from a second vertical plane containing the second edge; and ii) a deflector vane attached leeward to the cover portion, such that a plane of the deflector vane is aligned with the first vertical plane;
wherein the device is placed on a stationary body; and the air current rotates the aerodynamic deflector relative to the wind turbine such that the cover portion shields vanes in an upwind direction from the air current; and the opening exposes vanes in a downwind direction directly to the air current.

28. The device of claim 27, wherein the deflector further comprises a plurality of photovoltaic solar cells for harvesting solar energy.

29. The device of claim 27, wherein each of the plurality of vanes comprises one or more photovoltaic solar cells for harvesting solar energy.
